(19) United States
(12) Patent Application Publication
(10) Pub. No.: US 2026/0033286 A1
(43) Pub. Date: Jan. 29, 2026

(54) DEVICE AND METHOD FOR CHANGING THE POSITION OF A CARRIER FOR MANUFACTURING A DISPLAY DEVICE, AND ELECTRONIC DEVICE

(71) Applicants: Samsung Display Co., LTD., Yongin-si (KR); ULVAC, INC., Chigasaki-shi (JP)

(72) Inventors: Kyung Hoon CHUNG, Yongin-si (KR); Daisuke IWASE, Chigasaki-shi (JP); Akira YUYAMA, Chigasaki-shi (JP); Hyun Woo CHO, Chigasaki-shi (JP); Jung Seob LEE, Yongin-si (KR); Yong Sic JEON, Yongin-si (KR); Hyeon Sik KIM, Yongin-si (KR); Yong YEO, Yongin-si (KR)

(21) Appl. No.: 19/187,104

(22) Filed: Apr. 23, 2025

(30) Foreign Application Priority Data
Jul. 29, 2024 (KR) 10-2024-0100065

(51) Int. Cl. H01L 21/683; H10K 71/16

(52) U.S. Cl. CPC H01L 21/6833; H10K 71/166

(57) ABSTRACT

An embodiment relates to a device for changing a position of a carrier for manufacturing a display device. The device includes: a driving object disposed under a transport unit for transporting the carrier in which a substrate and a substrate tray are accommodated; a first rotating object connected to a first side of the driving object; a second rotating object connected to a second side of the driving object, opposite to the first side; a connecting portion connecting the first rotating object and the second rotating object to each other; and a support member on the connecting portion.

This application claims priority to Korean Patent Application No. 10-2024-0100065, filed on Jul. 29, 2024, and all the benefits accruing therefrom under 35 U.S.C. § 119, the content of which in its entirety is herein incorporated by reference.

### BACKGROUND

### 1. Field

An embodiment relates to a manufacturing device for a display device, and more particularly, to a device and method for changing the position of a carrier for manufacturing a display device and an electronic device, by which deposition precision can be improved.

### 2. Description of the Related Art

Organic light emitting diode displays have self-luminous characteristics and, unlike liquid crystal displays, do not require a separate light source and thus can be reduced in thickness and weight. In addition, organic light emitting diode displays are attracting attention as next-generation displays for portable electronic devices due to their high-quality characteristics such as low power consumption, high luminance, and high response speed.

### SUMMARY

Aspects of the present disclosure provide a device and method for changing the position of a carrier for manufacturing a display device and an electronic device, by which deposition precision can be improved.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to an aspect of the present disclosure, there is provided a device for changing a position of a carrier for manufacturing a display device. The device includes: a driving object disposed under a transport unit for transporting the carrier in which a substrate and a substrate tray are accommodated; a first rotating object connected to a first side of the driving object; a second rotating object connected to a second side of the driving object, opposite to the first side; a connecting portion connecting the first rotating object and the second rotating object to each other; and a support member on the connecting portion.

According to another aspect of the present disclosure, there is provided a method of changing a position of a carrier for manufacturing a display device. The method includes: preparing a position changing device which includes a driving object, a first rotating object connected to a first side of the driving object and including a first support, a second rotating object connected to a second side of the driving object opposite to the first side and including a second support, a connecting portion connecting the first rotating object and the second rotating object to each other, and a support member on the connecting portion; loading the carrier, in which a substrate tray and a substrate are accommodated, onto the position changing device in a horizontal direction through a transport unit; bringing the support member and an electrostatic chuck of the substrate tray into contact with each other by rotating the position changing device in a first direction, which is a direction toward the carrier; driving the electrostatic chuck so that the electrostatic chuck provides an electrostatic force; and changing the position of the carrier from the horizontal position to a vertical position by further rotating the position changing device along the first direction.

According to another aspect of the present disclosure, there is provided an electronic device manufactured by a device for changing the position of a carrier for manufacturing a display device. The electronic device includes: a display device, wherein the device includes: a driving object disposed under a transport unit for transporting the carrier in which a substrate and a substrate tray are accommodated; a first rotating object connected to a first side of the driving object; a second rotating object connected to a second side of the driving object; a connecting portion connecting the first rotating object and the second rotating object to each other; and a support member on the connecting portion.

According to a device and method for changing the position of a carrier for manufacturing a display device, deposition precision can be improved.

However, the effects of the present disclosure are not restricted to the one set forth herein. The above and other effects of the present disclosure will become more apparent to one of daily skill in the art to which the present disclosure pertains by referencing the claims.

### BRIEF DESCRIPTION OF THE DRAWINGS

These and/or other aspects will become apparent and more readily appreciated from the following description of the embodiments, taken in conjunction with the accompanying drawings in which:

FIG. 1 is a schematic diagram of a deposition device according to an embodiment;

FIG. 2 is a perspective view of a substrate tray of FIG. 1;

FIG. 3 is a perspective view of a carrier disposed on a transport track;

FIG. 4 illustrates a state where the substrate tray of FIG. 2 is coupled to the carrier of FIG. 3;

FIG. 5 is a perspective view for explaining an attaching device, a position changing device, an attaching method, and a position changing method for a display device according to an embodiment;

FIG. 6 is a detailed configuration diagram of the position changing device of FIG. 5;

FIG. 7 is an enlarged view of part A of FIG. 6;

FIGS. 8, 9, 10 and 11 are views for explaining a method of changing the position of the carrier using the position changing device according to an embodiment; and

FIG. 12 is a cross-sectional view of a support and a gripper of the attaching device for a display device according to the embodiment.

FIG. 13 is a block diagram of an electronic device according to one embodiment.

FIGS. 14, 15, and 16 are schematic diagrams of electronic devices according to various embodiments.

### DETAILED DESCRIPTION

The present invention will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art.

It will also be understood that when a layer is referred to as being “on” another layer or substrate, it can be directly on the other layer or substrate, or intervening layers may also be present. The same reference numbers indicate the same components throughout the specification. In the attached figures, the thickness of layers and regions is exaggerated for clarity.

Although the terms “first”, “second”, etc. may be used herein to describe various elements, these elements, should not be limited by these terms. These terms may be used to distinguish one element from another element. Thus, a first element discussed below may be termed a second element without departing from teachings of one or more embodiments. The description of an element as a “first” element may not require or imply the presence of a second element or other elements. The terms “first”, “second”, etc. may also be used herein to differentiate different categories or sets of elements. For conciseness, the terms “first”, “second”, etc. may represent “first-category (or first-set)”, “second-category (or second-set)”, etc., respectively.

Features of various embodiments of the present disclosure may be combined partially or totally. As will be clearly appreciated by those skilled in the art, technically various interactions and operations are possible. Various embodiments can be practiced individually or in combination.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof. Hereinafter, exemplary embodiments of the present disclosure will be described with reference to the accompanying drawings.

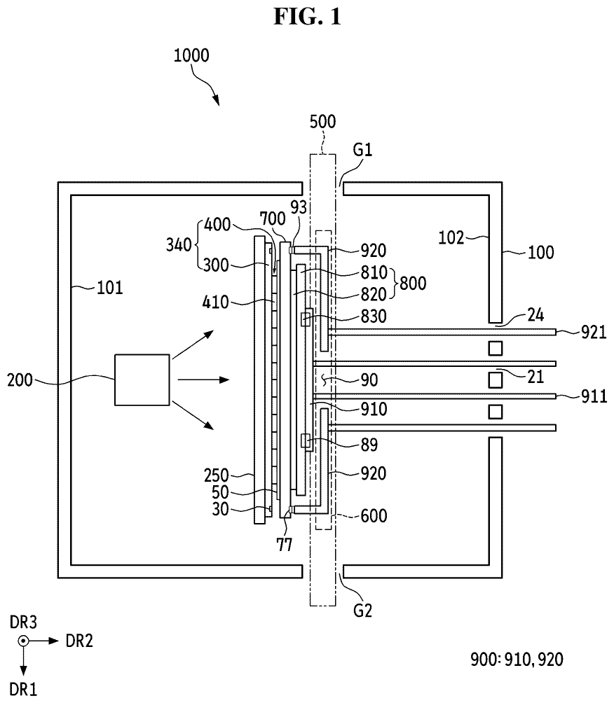

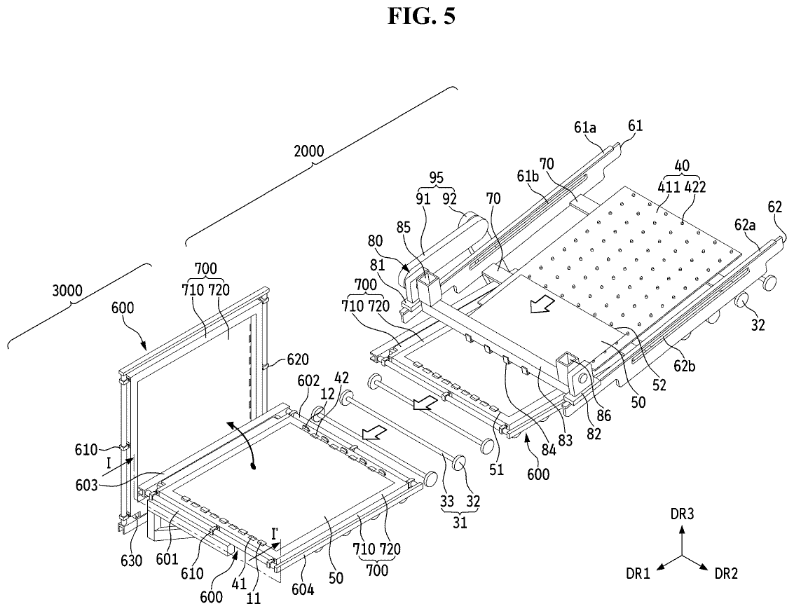

A manufacturing device for a display device according to an embodiment may include a deposition device 1000 of FIG. 1 (e.g., a deposition device for a substrate for a display device), an attaching device 2000 of FIG. 5 (e.g., a device for attaching a substrate for a display device to a substrate tray), and a position changing device 3000 (e.g., a device for changing the position of a carrier for manufacturing a display device).

FIG. 1 is a schematic diagram of a deposition device 1000 according to an embodiment. In FIG. 1, a reverse direction (hereinafter, referred to as a third reverse direction) of a third direction DR3 may be the direction of gravity.

The deposition device 1000 for a display device according to the embodiment may include a chamber 100, a deposition source 200, a deposition stage 250, a mask structure 340, a substrate tray 700, a magnet plate 800, a transport track 500, a carrier 600, and a driving mechanism 900 as illustrated in FIG. 1.

The chamber 100 may define a deposition space in which a deposition process is performed. A layer deposition process for manufacturing an organic light emitting diode display device may be performed inside the chamber 100. The chamber 100 may be a vacuum chamber 100. The deposition source 200, the deposition stage 250, the driving mechanism 900, and a portion of the transport track 500 described above may be disposed inside the chamber 100. When a deposition process is in progress, the deposition source 200, the deposition stage 250, the mask structure 340, a substrate 50, the substrate tray 700, the magnet plate 800, a portion of the transport track 500, and the driving mechanism 900 may be disposed inside the chamber 100.

The deposition source 200 may be disposed inside the chamber 100. For example, the deposition source 200 may be disposed between a first inner wall 101 of the chamber 100 and the deposition stage 250. The deposition source 200 may provide a deposition material. The deposition material from the deposition source 200 may pass through an opening of the deposition stage 250 and move toward the mask structure 340. Specifically, the deposition source 200 may evaporate a deposition material such as an organic material or an electrode material by heating the deposition material to a high temperature, and the evaporated deposition material may be deposited on the substrate 50 through pattern holes of the mask structure 340. The organic material may be, for example, a material for manufacturing a hole injection layer, a hole transport layer, a light emitting layer, an electron transport layer, and an electron injection layer disposed between an anode and a cathode of an organic light emitting diode. The substrate 50 may be, for example, a substrate used in a display device including organic light emitting diodes.

The deposition stage 250 may be disposed on the deposition source 200. For example, the deposition stage 250 may be disposed between the deposition source 200 and the mask structure 340. The deposition stage 250 may be disposed in a fixed state inside the chamber 100. The deposition stage 250 may be tilted toward the deposition source 200. For example, the deposition stage 250 may be tilted in a second reverse direction of a second direction DR2 with respect to the third direction DR3. Accordingly, an angle formed between a surface of the deposition stage 250 which faces the deposition source 200 and the ground (e.g., a bottom surface of the chamber 100) on which the deposition stage 250 is disposed may be an acute angle. Here, supports may be disposed on a lower side of the deposition stage 250 to protrude from a surface of the lower side along the second direction DR2. The deposition stage 250 may be shaped like a quadrangular frame with a penetrated central portion. For example, the deposition stage 250 may have an opening in the central portion.

The mask structure 340 may be disposed on the deposition stage 250. For example, the mask structure 340 may be disposed between the deposition stage 250 and the substrate tray 700. The mask structure 340 may be disposed on the supports of the deposition stage 250. Here, since the deposition stage 250 is tilted, the mask structure 340 may also be tilted on the deposition stage 250. The mask structure 340 may include a frame 300 and a mask 400.

The frame 300 may be disposed on the deposition stage 250. For example, the frame 300 may be disposed between the deposition stage 250 and the mask 400. The frame 300 may be shaped like a quadrangular frame with a penetrated central portion. For example, the frame 300 may define an opening in the central portion. Grooves 30 may be disposed at both edges of the frame 300. The frame 300 may include a magnetic material. For example, the frame 300 may include a material (e.g., iron (Fe)) that can be attracted to a magnet.

The mask 400 may be disposed on the frame 300. For example, the mask 400 may be disposed between the frame 300 and the substrate tray 700. The mask 400 may be disposed on the frame 300 to cover the opening of the frame 300. Edges of the mask 400 may be attached to the frame 300. For example, the mask 400 may be attached to the frame 300 by welding. The mask 400 may be a fine metal mask (FMM).

The mask 400 may include a plurality of sub-masks 410 (or mask sticks). Each of the sub-masks 410 may have a rectangular shape extending in the third direction DR3. The sub-masks 410 may be arranged along a first direction DR1. Adjacent sub-masks 410 may contact each other. Each sub-mask 410 excluding both edges may be disposed on the opening 39 of the frame 300. Although not illustrated, each sub-mask 410 may have a plurality of pattern holes penetrating the sub-mask 410 in the second direction DR2. A deposition material from the deposition source 200 may be deposited on the substrate 50 through the pattern holes of each sub-mask 410. Each sub-mask 410 may be made of a material including a magnetic material (e.g., iron (Fe)). For example, each sub-mask 410 may include a material that is attracted to a magnet.

The substrate tray 700 may be disposed on the mask structure 340. For example, the substrate tray 700 may be disposed between the mask 400 of the mask structure 340 and the magnet plate 800. The substrate tray 700 may transport the substrate 50. Here, the substrate tray 700 may adsorb the substrate 50 using an electrostatic force. For example, the substrate tray 700 may provide a surface on which the substrate 50 is placed while serving as an electrostatic chuck which adsorbs and fixes the substrate 50 to the surface of the substrate tray 700. The substrate tray 700 may be made of a material including ceramic or titanium.

The magnet plate 800 may be disposed on the substrate tray 700. For example, the magnet plate 800 may be disposed between the substrate tray 700 and the driving mechanism 900. The magnet plate 800 may be disposed on the substrate tray 700 to face the substrate tray 700. The magnet plate 800 may provide a magnetic force. For example, the magnet plate 800 may provide a magnetic force so that the metal mask 400 described above is closely attached to the substrate 50.

The magnet plate 800 may include a base member 810 and a plurality of magnets 820 disposed on the base member 810. For example, the magnets 820 may be disposed on the base member 810. As a specific example, when a side surface of the base member 810 which faces the substrate tray 700 is defined as a first surface, the magnets 820 may be disposed on the first surface of the base member 810. Each magnet 820 may include, for example, a permanent magnet.

Each of the magnets 820 may have an N pole and an S pole. A plurality of magnets 820 disposed along the first direction DR1 may be disposed such that opposite polarities face each other in the first direction DR1. A plurality of magnets 820 disposed along the second direction DR2 may be disposed such that opposite polarities face each other.

When a surface opposite the first surface of the base member 810 is defined as a second surface of the base member 810, a plurality of magnetic objects 830 may be disposed on the second surface of the base member 810. For example, the magnetic objects 830 may be disposed on the second surface in coupling grooves of the base member 810. For example, the magnetic objects 830 may include a material (e.g., iron (Fe)) that can be attracted to a magnet.

The driving mechanism 900 may include a first driving mechanism 910 and a second driving mechanism 920.

The first driving mechanism 910 may be disposed between the magnet plate 800 and the second driving mechanism 920. For example, the first driving mechanism 910 may be disposed between the base member 810 of the magnet plate 800 and the second driving mechanism 920. The first driving mechanism 910 may include magnets 89. For example, the magnets 89 may be disposed on a surface opposite a surface of the first driving mechanism 910 which is connected to a first driving shaft 911. The magnets 89 of the first driving mechanism 910 may correspond to (or overlap) the magnetic objects 830 of the magnet plate 800. The magnets 89 may include permanent magnets.

The magnet plate 800 may be detachably attached to the first driving mechanism 910. For example, the base member 810 of the magnet plate 800 may be detachably attached to the magnets 89 of the first driving mechanism 910. In other words, the magnetic objects 830 of the base member 810 may be attached to the magnets 89 of the first driving mechanism 910 by a magnetic force from the magnets 89 of the first driving mechanism 910. The first driving mechanism 910 may move toward the deposition source 200 or in the opposite direction within the chamber 100. For example, the first driving mechanism 910 may move along the second reverse direction or the second direction DR2. To this end, according to an embodiment, the first driving mechanism 910 may be connected to the first driving shaft 911 which is extended along the second reverse direction or retracted along the second direction DR2. The first driving shaft 911 may be connected to an external driver through a hole 90 of the second driving mechanism 920 and a hole 21 of the chamber 100. In addition, the first driving mechanism 910 may move further in the first direction DR1, a first reverse direction, the third direction DR3, or the third reverse direction. In this case, the first driving shaft 911 may move further in the first direction DR1, the first reverse direction, the third direction DR3, or the third reverse direction. The movement of the magnet plate 800 attached to the first driving mechanism 910 may be controlled by the movement of the first driving mechanism 910.

The second driving mechanism 920 may be disposed between the first driving mechanism 910 and a second inner wall 102 of the chamber 100. The second driving mechanism 920 may include electro-permanent magnets 93. The substrate tray 700 may be attached to the second driving mechanism 920. For example, the substrate tray 700 may be attached to the second driving mechanism 920 as magnetic objects 77 of the substrate tray 700 are attached to the electro-permanent magnets 93 of the second driving mechanism 920. The electro-permanent magnets 93 may be disposed at both edges of the second driving mechanism 920. The magnetic objects 77 may be disposed at both edges of the substrate tray 700 to correspond to the electro-permanent magnets 93. The magnetic objects 77 may include a magnetic material that is attracted to a magnet, such as iron (Fe).

The second driving mechanism 920 may also include electromagnets instead of the electro-permanent magnets 93. The second driving mechanism 920 may move toward the deposition source 200 or in the opposite direction within the chamber 100. For example, the second driving mechanism 920 may move along the second reverse direction or the second direction DR2. To this end, according to an embodiment, the second driving mechanism 920 may be connected to a second driving shaft 921 which is extended along the second reverse direction or retracted along the second direction DR2. In addition, the second driving mechanism 920 may move further in the first direction DR1, the first reverse direction, the third direction DR3, or the third reverse direction. In this case, the second driving shaft 921 may move further in the first direction DR1, the first reverse direction, the third direction DR3, or the third reverse direction. The movement of the substrate tray 700 attached to the second driving mechanism 920 may be controlled by the movement of the second driving mechanism 920. The second driving mechanism 920 may perform an alignment operation between the substrate 50 of the substrate tray 700 and the mask structure 340 by controlling the position of the substrate tray 700 attached to the second driving mechanism 920.

The transport track 500 may be, for example, disposed inside the chamber 100 and outside the chamber 100 to pass through a first gate G1 and a second gate G2 of the chamber 100. The transport track 500 may extend along the first direction DR1. The first gate G1 and the second gate G2 may face each other.

The carrier 600 may move along the transport track 500. For example, the carrier 600 may move along the transport track 500 in a magnetic levitation manner. The carrier 600 may transport the substrate tray 700.

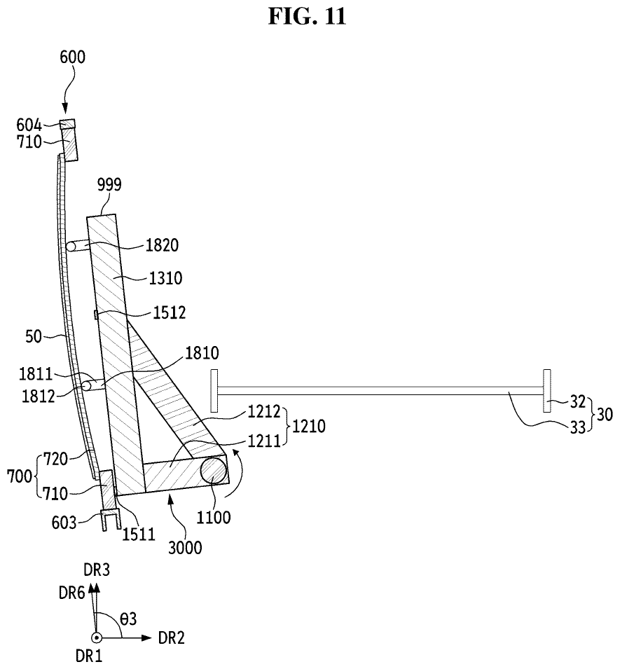

As described above, an upper side of the deposition stage 250 may be tilted toward the deposition source 200 (e.g., tilted at the same angle as the carrier 600 illustrated in FIG. 11 to be described later). Accordingly, the mask structure 340, the substrate tray 700, the substrate 50, the magnet plate 800, the first driving mechanism 910, the second driving mechanism 920, the transport track 500, and the carrier 600 described above may also be tilted at the same angle as the deposition stage 250. Accordingly, particles generated during a deposition process on the substrate 50 may fall in the direction of gravity without sticking to the substrate 50. Therefore, the substrate 50 can be prevented from being contaminated by the particles.

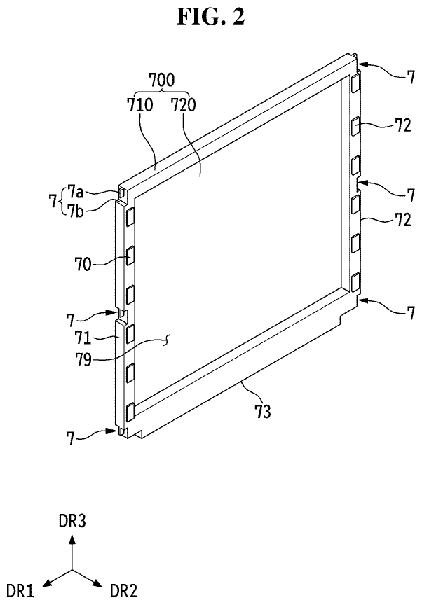

FIG. 2 is a perspective view of the substrate tray 700 of FIG. 1.

As illustrated in FIG. 2, the substrate tray 700 may include a support plate 710 and an electrostatic chuck 720.

The support plate 710 may be shaped like a quadrangular frame with a penetrated central portion. For example, the support plate 710 may have an opening 79 in the central portion.

The electrostatic chuck 720 may be disposed on the support plate 710. For example, the electrostatic chuck 720 may be disposed between the support plate 710 and the substrate 50. Here, the electrostatic chuck 720 may cover the opening 79 of the support plate 710. The substrate 50 may be placed on the electrostatic chuck 720. The electrostatic chuck 720 may adsorb the substrate 50 using an electrostatic force.

At least one detachable member 7 may be disposed at edges of the substrate tray 700. For example, a detachable member 7 may be disposed near each corner of the quadrangular support plate 710. Specifically, the support plate 710 may have six detachable members 7. Here, three of the six detachable members 7 may be disposed at the top, middle and bottom of a first side 71 of the substrate tray 700, respectively, and the remaining three detachable members 7 may be disposed at the top, middle and bottom of a second side 72 of the substrate tray 700, respectively. The first side 71 and the second side 72 of the substrate tray 700 may face each other along the first direction DR1.

Each detachable member 7 may include a coupling tip 7a and a separation groove 7b disposed adjacent to each other in the third direction DR3. The coupling tip 7a may be disposed higher than the separation groove 7b. For example, in one detachable member 7, the coupling tip 7a may be disposed higher than the separation groove 7b in the third direction DR3. The coupling tip 7a may have a smaller thickness (e.g., size in the second direction DR2) than other parts of the substrate tray 700. For example, the coupling tip 7a may have a smaller thickness (e.g., size in the second direction DR2) than other parts of the support plate 710. The separation groove 7b may be recessed from the first side 71 of the substrate tray 700 (e.g., the support plate 710) toward the second side 72 or may be recessed from the second side 72 toward the first side 71. For example, separation grooves 7b disposed on different sides and facing each other may be recessed toward each other.

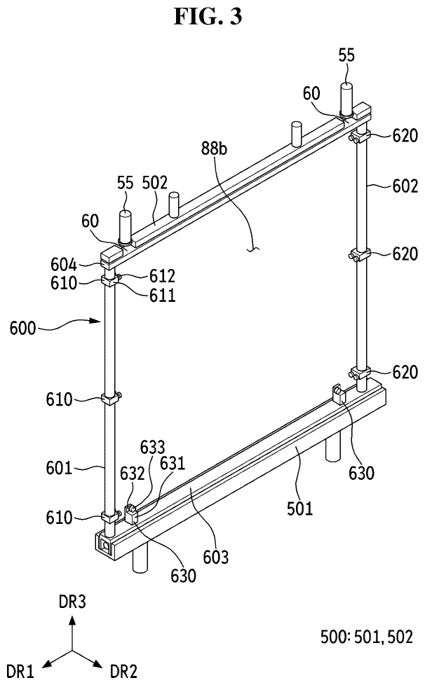

FIG. 3 is a perspective view of a carrier disposed on a transport track. Here, FIG. 3 may be a perspective view of the carrier 600 disposed on the transport track 500 of FIG. 1.

The carrier 600 may move along the transport track 500. The transport track 500 may include a lower track 501 and an upper track 502 facing each other in the third direction DR3. Therefore, the carrier 600 may be disposed between the lower track 501 and the upper track 502. The carrier 600 may move along the transport track 500 between the lower track 501 and the upper track 502.

The carrier 600 may be shaped like a quadrangular frame as in the example illustrated in FIG. 3. However, the shape of the carrier 600 is not limited thereto and can be changed to various shapes.

The carrier 600 may include a plurality of bars 601, 602, 603 and 604 and a plurality of support members 610, 620 and 630 as illustrated in FIG. 3. For example, the carrier 600 may include a first bar 601, a second bar 602, a third bar 603, and a fourth bar 604 connected to each other. The substrate tray 700 may be placed in an area (e.g., an opening 88b) surrounded and defined by the first bar 601, the second bar 602, the third bar 603, and the fourth bar 604.

The first bar 601 and the second bar 602 may face each other in the first direction DR1. The third bar 603 and the fourth bar 604 may face each other in the third direction DR3. The first bar 601 may be disposed between an end of the third bar 603 and an end of the fourth bar 604. The second bar 602 may be disposed between the other end of the third bar 603 and the other end of the fourth bar 604.

The support members 610, 620 and 630 may include one or more first support members 610 extending from the first bar 601, one or more second support members 620 extending from the second bar 602, and one or more third support members 630 extending from the third bar 603.

Each of the first support members 610 may include an extension portion 611 and a plurality of protrusions 612. A side of the extension portion 611 may be connected to the first bar 601. The extension portion 611 may extend from the first bar 601 toward the second bar 602. The protrusions 612 (e.g., two protrusions 612) may be disposed on the other side of the extension portion 611. The protrusions 612 may be rotatably connected to the other side of the extension portion 611. For example, each of the protrusions 612 may rotate about an axis parallel to the first direction DR1. The protrusions 612 may face each other in the second direction DR2. Each of the protrusions 612 may have a cylindrical shape. However, the shape of the protrusions 612 is not limited thereto and can be changed to various shapes.

The second support members 620 may have the same configuration as the first support members 610 described above. However, an extension portion of each of the second support members 620 may extend from the second bar 602 toward the first bar 601.

Each of the third support members 630 may include an extension portion 631, a protruding portion 632, and a protrusion 633. A side of the extension portion 631 may be connected to the third bar 603. The extension portion 631 may extend from the third bar 603 toward the fourth bar 604. The protruding portion 632 may be disposed on the other side of the extension portion 631. The protrusion 633 may be disposed on a side of the protruding portion 632. The protrusion 633 may be rotatably connected to the side of the protruding portion 632. For example, the protrusion 633 may rotate about an axis parallel to the second direction DR2. The protrusion 633 may have a cylindrical shape. However, the shape of the protrusion 633 is not limited thereto and can be changed to various shapes.

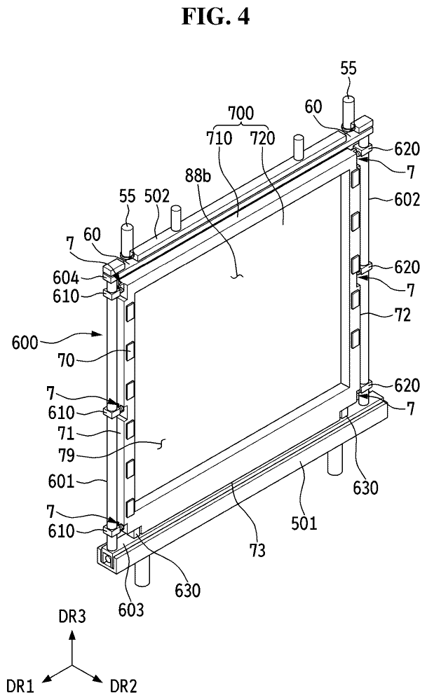

FIG. 4 illustrates a state where the substrate tray 700 of FIG. 2 is coupled to the carrier 600 of FIG. 3.

As illustrated in FIG. 4, the first support members 610, the second support members 620, and the third support members 630 may support the substrate tray 700.

Each of the first support members 610 may support the first side 71 of the substrate tray 700. For example, the first side 71 of the substrate tray 700 may be placed and supported between the protrusions 612 of each first support member 610. Specifically, the first side 71 may be supported as a coupling tip 7a of the first side 71 is placed between the protrusions 612 of each first support member 610.

Each of the second support members 620 may support the second side 72 of the substrate tray 700. For example, the second side 72 of the substrate tray 700 may be placed and supported between protrusions of each second support member 620. Specifically, the second side 72 may be supported as a coupling tip 7a of the second side 72 is placed between the protrusions of each second support member 620.

Each of the third support members 630 may support a third side 73 of the substrate tray 700. For example, the third side 73 of the substrate tray 700 may be placed and supported on the protrusion 633 of each third support member 630. Here, the protrusion 633 of each third support member 630 may contact the third side 73.

The deposition device 1000 of the embodiment may further include pushers 55. The pushers 55 may be disposed on the carrier 600. For example, the pushers 55 may be disposed on the fourth bar 604 of the carrier 600. Specifically, the pushers 55 may face the fourth bar 604 through openings 60 of the upper track 502. The pushers 55 and the openings 60 of the upper track 502 may be disposed inside the chamber 100.

The pushers 55 may move toward the fourth bar 604 or in the opposite direction. For example, the pushers 55 may move along the third reverse direction or the third direction DR3. Here, when the pushers 55 move along the third reverse direction, the lower track 501 may also move along the third reverse direction. For example, the pushers 55 and the lower track 501 may move together along the third reverse direction.

When the pushers 55 move along the third reverse direction, they may contact the fourth bar 604 through the openings 60 of the upper track 502. At this time, the fourth bar 604 may be lowered by the pressure of the pushers 55. In other words, as the pushers 55 press the fourth bar 604 in the third reverse direction, the carrier 600 may move in the third reverse direction. Accordingly, the first support members 610, the second support members 620, and the third support members 630 may be moved in the third reverse direction. Therefore, the protrusions 612 of each first support member 610 and the protrusions of each second support member 620 may be placed to face each other through the separation grooves 7b of the substrate tray 700. In other words, the protrusions 612 of each first support member 610 and a corresponding coupling tip 7a of the first side 71 of the substrate tray 700 do not contact each other, and the protrusions 612 of each second support member 620 and a corresponding coupling tip of the second side 72 of the substrate tray 700 do not contact each other. In addition, as the carrier 600 is lowered along the third reverse direction by the pushers 55 as described above, the third support members 630 and the substrate tray 700 may be separated from each other. For example, since the protrusions 612 of the second support members 620 and the third side 73 of the substrate tray 700 are separated from each other, the protrusions 633 of the third support members 630 and the third side 73 do not contact each other. Accordingly, the substrate tray 700 is no longer supported by the carrier 600. Therefore, the substrate tray 700 can easily move in the second direction DR2 and the second reverse direction without being interfered with by the carrier 600.

The substrate tray 700 and the substrate 50 described above may be provided from the attaching device 2000. For example, the substrate tray 700 and the substrate 50 from the attaching device 2000 may be provided to the above-described deposition device 1000 through the position changing device 3000.

An attaching device 2000 for a display device and a position changing device 3000 for a display device according to an embodiment will now be described in detail as follows.

FIG. 5 is a perspective view for explaining an attaching device 2000, a position changing device 3000, an attaching method, and a position changing method for a display device according to an embodiment.

In order to explain the attaching method and the position changing method, three carriers 600 are illustrated in FIG. 5, and all of the three carriers 600 are the same carrier 600. For example, after an attaching process in the attaching device 2000, the carrier 600 may be moved to the position changing device 3000 through a transport unit 31 and may be changed from a horizontal position to a vertical position in the position changing device 3000. In other words, FIG. 5 sequentially shows positions of the carriers 600 transported along the transport unit 31 over time.

The substrate tray 700 may further include a plurality of first clamps 11 and a plurality of first holes 41 disposed at an edge of the support plate 710 and a plurality of second clamps 12 and a plurality of second holes 42 disposed at the other edge of the support plate 710 as illustrated in FIG. 5. The first clamps 11 and the first holes 41 may be disposed adjacent to the first bar 601 of the carrier 600. The second clamps 12 and the second holes 42 may be disposed adjacent to the second bar 602 of the carrier 600. The first clamps 11 and the first holes 41 may be disposed alternately along the second direction DR2. The second clamps 12 and the second holes 42 may be disposed alternately along the second direction DR2. The first clamps 11, the first holes 41, the second clamps 12, and the second holes 42 may be exposed to the outside through through-holes penetrating the electrostatic chuck 720. The first holes 41 and the second holes 42 may be disposed to correspond to grippers 84 which will be described later.

The attaching device 2000 for a display device according to the embodiment may include, as illustrated in FIG. 5, the transport unit 31, an attaching stage 40, a movable object 80, a first driving arm 95, a first guide bar 61, a second guide bar 62, and a plurality of support bars 70.

The transport unit 31 may be disposed along the first direction DR1. The transport unit 31 may transport the carrier 600 along the first direction DR1. The transport unit 31 may include pairs of rollers 32 and a connecting shaft 33 connecting each pair of the rollers 32. The connecting shaft 33 may extend along the second direction DR2. Each pair of the rollers 32 may be connected to a side and the other side of the connecting shaft 33, respectively. Each pair of the rollers 32 may be rotatably connected to the connecting shaft 33, respectively.

The first guide bar 61 and the second guide bar 62 may face each other. For example, the first guide bar 61 and the second guide bar 62 may face each other in the second direction DR2.

The first guide bar 61 may include a first rail 61a and a first opening 61b. The first rail 61a may be disposed on the first guide bar 61 along an extending direction (or a longitudinal direction; e.g., the first direction DR1) of the first guide bar 61. The first opening 61b may penetrate the first guide bar 61. The substrate 50 may be loaded into the attaching device 2000 from the outside through the first opening 61b or may be unloaded from the attaching device 2000 to the outside through the first opening 61b.

The second guide bar 62 may include a second rail 62a and a second opening 62b. The second rail 62a may be disposed on the second guide bar 62 along an extending direction (or a longitudinal direction; e.g., the first direction DR1) of the second guide bar 62. The second opening 62b may penetrate the second guide bar 62. The substrate 50 may be loaded into the attaching device 2000 from the outside through the second opening 62b or may be unloaded from the attaching device 2000 to the outside through the second opening 62b.

The support bars 70 may be disposed between the first guide bar 61 and the second guide bar 62. The support bars 70 may connect the first guide bar 61 and the second guide bar 62 to each other. For example, an end of each of the support bars 70 may be connected to an inner surface of the first guide bar 61, and the other end of each of the support bars 70 may be connected to an inner surface of the second guide bar 62.

The attaching stage 40 may be disposed on the support bars 70. For example, the attaching stage 40 may be disposed on the support bars 70 between the first guide bar 61 and the second guide bar 62. The attaching stage 40 may be connected to the support bars 70. The attaching stage 40 may include a base plate 411 and a plurality of support pins 422.

The base plate 411 of the attaching stage 40 may be disposed on the support bars 70. The base plate 411 may be connected to the support bars 70.

The support pins 422 of the attaching stage 40 may be disposed on the base plate 411. The support pins 422 may be shaped like pillars protruding upward from the base plate 411. The support pins 422 may be coupled to the base plate 411. For example, an end of each support pin 422 may be coupled to the base plate 411. A spherical ball rotatably connected to each support pin 422 may be disposed at the other end of the support pin 422. The support pins 422 may be disposed in a matrix form on the base plate 411.

The movable object 80 may be disposed on the attaching stage 40. For example, the movable object 80 may be disposed on the attaching stage 40 to overlap the attaching stage 40. The movable object 80 may be movably coupled to the first guide bar 61 and the second guide bar 62. The movable object 80 may be disposed between the first guide bar 61 and the second guide bar 62 and may move along the first rail 61a of the first guide bar 61 and the second rail 62a of the second guide bar 62. For example, the movable object 80 may move on the attaching stage 40 along the first direction DR1 or the first reverse direction while being guided by the first rail 61a and the second rail 62a. The movable object 80 may include a support 83, a first driver 85, a second driver 86, a first coupling portion 81, a second coupling portion 82, and the grippers 84.

The support 83 of the movable object 80 may be disposed between the first guide bar 61 and the second guide bar 62. The support 83 may extend along the second direction DR2. The support 83 may be disposed on the attaching stage 40 to overlap the attaching stage 40. The support 83 may have an “r”-shaped cross section.

The grippers 84 of the movable object 80 may be disposed on the support 83. The grippers 84 may be disposed on a lower side of the support 83. The grippers 84 may be arranged in a row along the support 83 in the second direction DR2 between the first guide bar 61 and the second guide bar 62. In other words, the grippers 84 may be disposed under the support 83 along the extending direction (e.g., the second direction DR2) of the support 83. The grippers 84 may be coupled to and supported by the support 83. The grippers 84 may have an “L” shaped cross section.

The first coupling portion 81 of the movable object 80 may be movably coupled to the first rail 61a of the first guide bar 61. The first coupling portion 81 may include a first wheel movably coupled to the first rail 61a. Therefore, the first coupling portion 81 may be moved along the first rail 61a by driving the first wheel.

The second coupling portion 82 of the movable object 80 may be movably coupled to the second rail 62a of the second guide bar 62. The second coupling portion 82 may include a second wheel movably coupled to the second rail 62a. Therefore, the second coupling portion 82 may be moved along the second rail 62a by driving the second wheel. A center of a rotation axis of the first wheel and a center of a rotation axis of the second wheel may be parallel to each other and may also coincide with each other. A rotation direction of the first wheel and a rotation direction of the second wheel may be the same.

The first driver 85 of the movable object 80 may be disposed on the support 83 on a side of the support 83. The first driver 85 may be connected to a side of the support 83 and a side of the first coupling portion 81. For example, the first driver 85 may include a first actuator connected to a side of the support 83. The first actuator may be extended (or expanded) and retracted under the control of the first driver 85. The first driver 85 may include a first rotating shaft rotatably connected to a side of the first coupling portion 81. The first driver 85 may be rotated clockwise or counterclockwise by the first rotating shaft. The first driver 85 may control the rotation direction of the first wheel of the first coupling portion 81.

The second driver 86 of the movable object 80 may be disposed on the support 83 on the other side of the support 83. The second driver 86 may be connected to the other side of the support 83 and a side of the second coupling portion 82. For example, the second driver 86 may include a second actuator connected to the other side of the support 83. The second actuator may be extended and retracted under the control of the second driver 86. The second driver 86 may include a second rotating shaft rotatably connected to a side of the second coupling portion 82. The second driver 86 may be rotated clockwise or counterclockwise by the second rotating shaft. A center of the second rotating shaft and a center of the first rotating shaft may be parallel to each other and may also coincide with each other. The second driver 86 may control the rotation direction of the second wheel of the second coupling portion 82.

The support 83 may be moved in a direction away from the first driver 85 and the second driver 86 or may be moved in a direction approaching the first driver 85 and the second driver 86 by the operation of the first actuator of the first driver 85 and the second actuator of the second driver 86. For example, when the first actuator and the second actuator operate in a direction in which they are extended, the support 83 may move in the direction away from the first driver 85 and the second driver 86. On the other hand, when the first actuator and the second actuator operate in a direction in which they are retracted, the support 83 may move in the direction approaching the first driver 85 and the second driver 86. Accordingly, a distance between the support 83 and the attaching stage 40 can be adjusted.

The support 83 may be rotated clockwise or counterclockwise about the first rotating shaft (or the second rotating shaft) by the operation of the first rotating shaft of the first driver 85 and the second rotating shaft of the second driver 86. Accordingly, the support 83 may be rotated clockwise or counterclockwise about the first rotating shaft of the first driver 85 (or the second rotating shaft of the second driver 86).

The first driving arm 95 may control a tilt angle of the first guide bar 61. The first driving arm 95 may be rotatably connected to the other side of the first coupling portion 81. The first driving arm 95 may include a first link 91 and a second link 92. A side of the first link 91 may be rotatably connected to the first coupling portion 81. For example, a side of the first link 91 may be connected to the first rotating shaft of the first driver 85. The other side of the first link 91 may be rotatably connected to the second link 92. A side of the second link 92 may be connected to a first driving motor.

Although not illustrated, a second driving arm may be further connected to the other side of the second coupling portion 82 to control a tilt angle of the second guide bar 62. The second driving arm may face the first driving arm 95 described above and may have substantially the same configuration as the first driving arm 95. For example, the second driving arm may be rotatably connected to the second coupling portion 82. The second driving arm may include a third link corresponding to the first link 91 and a fourth link corresponding to the second link 92. A side of the third link may be rotatably connected to the second coupling portion 82. For example, a side of the third link may be connected to the second rotating shaft of the second driver 86. The other side of the third link may be rotatably connected to the fourth link. A side of the fourth link may be connected to a second driving motor.

The tilt angles of the first guide bar 61 and the second guide bar 62 may be controlled by driving the links of the first driving arm 95 (e.g., the first link 91 and the second link 92) and the links of the second driving arm (e.g., the third link and the fourth link). Accordingly, tilt angles of the support bars 70 connected to the guide bars 61 and 62 may be controlled. In addition, as the tilt angles of the support bars 70 are controlled, a tilt angle of the attaching stage 40 connected to the support bars 70 may be controlled. Consequently, the tilt angle of the attaching stage 40 may be controlled by driving the links of the first driving arm 95 (e.g., the first link 91 and the second link 92) and the links of the second driving arm (e.g., the third link and the fourth link).

The operation of the attaching device 2000 according to the embodiment will be described in detail as follows.

First, the carrier 600 (e.g., the carrier 600 in which the substrate tray 700 is accommodated) may be placed on the transport unit 31 of the attaching device 2000, and the attaching stage 40 may be placed on the carrier 600 to overlap the carrier 600. At this time, the movable object 80 may be placed at an end of each of the first guide bar 61 and the second guide bar 62 so as not to cover the first opening 61b of the first guide bar 61 and the second opening 62b of the second guide bar 62. For example, when a transport direction (e.g., the first direction DR1) of the transport unit 31 with respect to the attaching stage 40 is defined as a downstream direction, and an opposite direction (or a reverse direction) of the transport direction of the rollers 32 of the transport unit 31 is defined as an upstream direction, the movable object 80 may be placed at an end of each of the first guide bar 61 and the second guide bar 62 in the downstream direction. In this case, the movable object 80 may not overlap the attaching stage 40 or may overlap an edge of the attaching stage 40.

Next, the substrate 50 may be loaded into the attaching device 2000 from the outside. For example, the substrate 50 supported by a robot arm may be loaded into the attaching device 2000. As a specific example, the robot arm may include a plurality of fingers spaced apart from each other, and the substrate 50 placed on the fingers may be loaded into the attaching device 2000 together with the fingers. For example, the fingers on which the substrate 50 is placed may pass through the first opening 61b of the first guide bar 61 to lie between the first guide bar 61 and the second guide bar 62. Accordingly, the attaching stage 40 may be placed under the fingers to overlap the fingers, and the carrier 600 (e.g., the carrier 600 in which the substrate tray 700 is accommodated) may be placed under the attaching stage 40 to overlap the attaching stage 40. In other words, the fingers may be placed between the attaching stage 40 and the substrate 50 between the first guide bar 61 and the second guide bar 62, the attaching stage 40 may be placed between the fingers and the carrier 600, and the carrier 600 may be placed between the attaching stage 40 and the transport unit 31. At this time, the attaching stage 40 may be maintained in a horizontal position. For example, the attaching stage 40 and the carrier 600 (or the substrate tray 700 accommodated in the carrier 600) may be placed parallel to each other. The fingers may be placed on the attaching stage 40 so as not to overlap the support pins 422 of the attaching stage 40.

Next, the fingers may be lowered toward the attaching stage 40. The lowered fingers may be placed between the support pins 422 of the attaching stage 40. As the fingers are lowered, the substrate 50 placed on the fingers may be supported by the support pins 422. In other words, as the fingers are lowered, the substrate 50 may be supported only by the support pins 422 instead of the fingers. At this time, a lower surface of the substrate 50 may contact the balls of the support pins 422.

Next, the fingers which have transported the substrate 50 may be taken out through the first opening 61b.

Next, the movable object 80 may be moved in the downstream direction (e.g., in the first direction DR1) along the first guide bar 61 and the second guide bar 62 and placed close to a first side (or edge) 51 of the substrate 50 on the attaching stage 40.

Next, the movable object 80 may be moved so that the grippers 84 of the movable object 80 are placed between the attaching stage 40 and the substrate 50. At this time, the grippers 84 placed between the support pins 422 may support the lower surface of the substrate 50 (e.g., a lower surface of the first side 51 of the substrate 50). For example, the grippers 84 may support the lower surface of the substrate 50 (e.g., the lower surface of the first side 51 of the substrate 50) at an edge of the attaching stage 40. In this state, the gripper 84 may grip the first side 51 of the substrate 50. Alternatively, the gripper 84 may only support the first side 51 of the substrate 50 without gripping it.

Next, the attaching stage 40 may be tilted while the first side 51 of the substrate 50 is supported by the grippers 84 as described above. For example, the attaching stage 40 may be tilted in the downstream direction as the first guide bar 61 and the second guide bar 62 are tilted under the control of the first driving arm 95 and the second driving arm. Specifically, the attaching stage 40 may be tilted at a predetermined angle so that an upper surface of the attaching stage 40 (e.g., a surface on which the support pins 422 are disposed) faces the downstream direction of the transport unit 31 and that a lower surface of the attaching stage 40 (e.g., a surface opposite the upper surface of the attaching stage 40) faces the upstream direction of the transport unit 31. Here, an angle formed by the upper surface of the tilted attaching stage 40 and the transport unit 31 in the downstream direction may be an obtuse angle. In addition, an angle formed by the lower surface of the tilted attaching stage 40 and the transport unit 31 in the upstream direction may be an obtuse angle.

Next, the movable object 80 may move in the downstream direction along the first guide bar 61 and the second guide bar 62 tilted toward the downstream direction, and the carrier 600 may also move on the transport unit 31 along the downstream direction. At this time, the substrate 50 on the support pins 422 may also move in the downstream direction along the tilted surface of the attaching stage 40 together with the movable object 80. For example, the substrate 50 may be moved along the downstream direction together with the movable object 80 while being supported (and/or gripped) by the grippers 84 of the movable object 80. Here, while the movable object 80 is moved in the downstream direction along the tilted first and second guide bars 61 and 62, the carrier 600 is moved in the downstream direction along the horizontal transport unit 31 which is not tilted. Therefore, as the movable object 80 and the carrier 600 are moved in the downstream direction, the grippers 84 of the movable object 80 may gradually approach the first holes 41 disposed in the substrate tray 700 of the carrier 600. When the grippers 84 of the movable object 80 overlap the first holes 41 of the substrate tray 700, respectively, the movement of the movable object 80 and the carrier 600 may be stopped.

Next, the movable object 80 may be lowered toward the first holes 41. For example, the support 83 of the movable object 80 may be lowered toward the first holes 41 under the control of the first driver 85 and the second driver 86. Then, the grippers 84 attached to the support 83 may be inserted into the first holes 41, respectively. For example, the grippers 84 may be respectively inserted into the first holes 41 such that they are located more toward the upstream direction in respective spaces of the first holes 41. Here, since a size of each first hole 41 in the first direction DR1 is larger than a size of each gripper 84 in the first direction DR1, when the grippers 84 are inserted into the first holes 41, respectively, there may be a free space (or gap) between each gripper 84 and each first hole 41. For example, when the grippers 84 are inserted into the first holes 41, there may be a free space in each first hole 41 so that the grippers 84 can move further in the downward direction. Here, as the grippers 84 are inserted into the first holes 41, a portion of the substrate 50 (e.g., the first side 51 of the substrate 50) may first contact the electrostatic chuck 720 of the substrate tray 700. If the grippers 84 are gripping the substrate 50, the grip of the grippers 84 on the substrate 50 may be released before the movable object 80 descends toward the first holes 41.

Next, with the grippers 84 inserted into the first holes 41, the movable object 80 may move a predetermined distance in the downstream direction and then stop. Then, the grippers 84 may be respectively moved to the free spaces of the first holes 41 along the downstream direction. Accordingly, as the grippers 84 move away from the first side 51 of the substrate 50, the first side 51 of the substrate 50 and the grippers 84 in contact with each other may be separated. At this time, the first side 51 of the substrate 50 may be moved in the downstream direction to contact the first clamps 11 of the substrate tray 700. In other words, the first side 51 of the substrate 50 may not be supported by the grippers 84 and may be supported by the first clamps 11. Here, the first clamps 11 may serve as stoppers that prevent the substrate 50 from moving in the downstream direction.

Next, the first clamps 11 in contact with the first side 51 of the substrate 50 may rotate toward an upper surface of the substrate 50 to clamp the substrate 50. Accordingly, the first side 51 of the substrate 50 and its surroundings may be supported and fixed by the first clamps 11.

Next, while the first side 51 of the substrate 50 is supported and fixed by the first clamps 11, the movable object 80 may be raised away from the first holes 41. Accordingly, the grippers 84 may be raised after being exposed to the outside within the first holes 41. Accordingly, the grippers 84 may be placed on the substrate 50 so as not to contact the substrate 50.

Next, while the first side 51 of the substrate 50 is supported and fixed by the first clamps 11, the carrier 600 may move along the downstream direction. In other words, while the attaching stage 40 remains stationary, the carrier 600 may move further along the downstream direction. Then, the electrostatic chuck 720 of the substrate tray 700 which has been covered by the attaching stage 40 may be gradually exposed, and the substrate 50 clamped by the first clamps 11 of the substrate tray 700 may be gradually moved in the downstream direction together with the substrate tray 700. Accordingly, the remaining portion of the substrate 50 on the attaching stage 40 may gradually contact the electrostatic chuck 720. In other words, the substrate tray 700 may be moved in the downstream direction by the movement of the carrier 600, and as the substrate tray 700 moves, it may pull the substrate 50 down from the attaching stage 40 (e.g., the attaching stage 40 tilted toward the downstream side) while gripping the first side 51 of the substrate 50 on the attaching stage 40. Therefore, as the carrier 600 (or the substrate tray 700 on the carrier 600) moves in the downstream direction, a contact area between the attaching stage 40 (e.g., the support pins 422 of the attaching stage 40) and the substrate 50 may gradually decrease, but a contact area between the electrostatic chuck 720 of the substrate tray 700 accommodated in the carrier 600 and the substrate 50 may gradually increase. Therefore, the substrate 50 on the attaching stage 40 may be transferred from the attaching stage 40 onto the electrostatic chuck 720 of the substrate tray 700 while being moved along the downstream direction.

Next, the carrier 600 may be moved further along the downstream direction to the extent that the carrier 600 and the attaching stage 40 no longer overlap each other. Accordingly, the substrate 50 may be completely moved from the attaching stage 40 to the electrostatic chuck 720 of the substrate tray 700. As the carrier 600 is moved along the downstream direction as described above, the substrate 50 may start to contact the electrostatic chuck 720 from the first side 51 of the substrate 50 closer to the downstream direction, and then a second side 52 of the substrate 50 may contact the electrostatic chuck 720 last. At this time, the second side 52 of the substrate 50 on the electrostatic chuck 720 may be placed close to the second clamps 12 and the second holes 42 of the substrate tray 700.

Next, the second clamps 12 may rotate toward the upper surface of the substrate 50 to clamp the substrate 50. Accordingly, the second side 52 of the substrate 50 and its surroundings may be supported and fixed by the second clamps 12. Accordingly, the substrate 50 may be supported and fixed on the electrostatic chuck 720 by the first clamps 11 and the second clamps 12.

Next, the carrier 600 having the substrate tray 700 (e.g., the substrate tray 700 on which the substrate 50 is placed) may be moved further in the downstream direction along the transport unit 31 and then loaded onto the position changing device 3000.

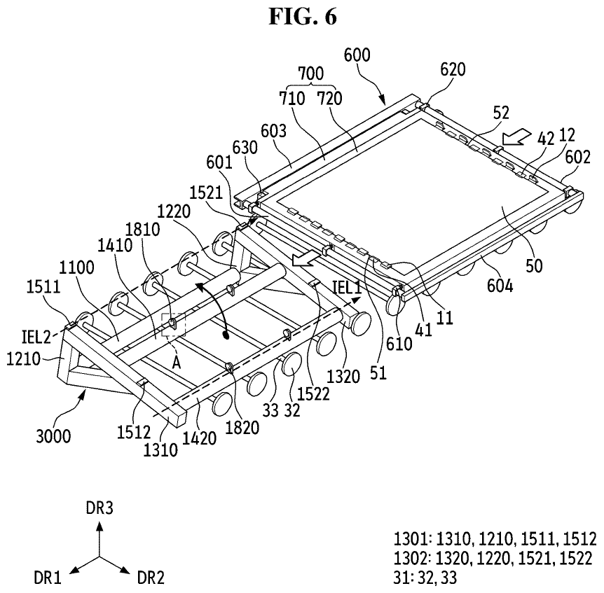

Here, the position changing device 3000 will be described in detail with reference to FIGS. 5 and 6 as follows.

FIG. 6 is a detailed configuration diagram of the position changing device 3000 of FIG. 5.

The position changing device 3000 may change the position of the carrier 600 as illustrated in FIG. 5. For example, the position changing device 3000 may change the position of the carrier 600, which is transported along the transport unit 31 after the above process of attaching the substrate 50 to the substrate tray 700, from a horizontal position to a vertical position. According to an embodiment, the position changing device 3000 may be placed under the transport unit 31 as illustrated in FIGS. 5 and 6.

The position changing device 3000 may include, as illustrated in FIG. 6, a driving object 1100, a first rotating object 1301, a second rotating object 1302, a first connecting portion 1410, a second connecting portion 1420, and one or more support members 1810 and 1820.

The driving object 1100 may be disposed on a lower side of the transport unit 31. The driving object 1100 may be disposed parallel to the transport direction of the transport unit 31. The driving object 1100 may extend along a direction (e.g., the first direction DR1) intersecting the transport direction of the transport unit 31. The driving object 1100 may rotate clockwise or counterclockwise. An axis of the driving object 1100 may be parallel to the transport direction of the transport unit 31. For example, the axis of the driving object 1100 may intersect an axis of the connecting shaft 33. The driving object 1100 may have a cylindrical shape.

The first rotating object 1301 and the second rotating object 1302 may face each other with the driving object 1100 interposed between them. The first rotating object 1301 and the second rotating object 1302 may have the same shape. The first rotating object 1301 and the second rotating object 1302 may have substantially the same configuration.

The first rotating object 1301 may be rotatably disposed on a first side of the driving object 1100. The first rotating object 1301 may include a first support 1310, a first coupling portion 1210, and protrusions 1511 and 1512.

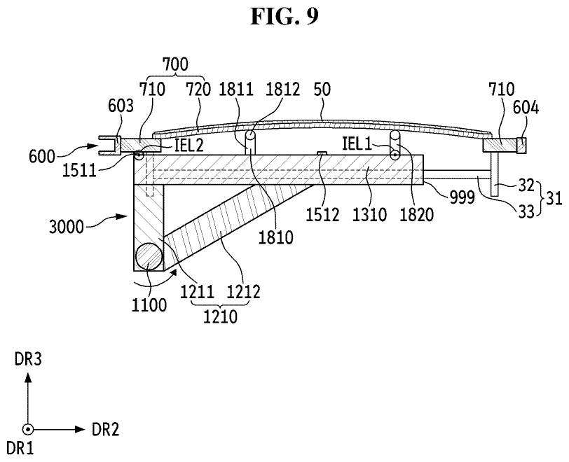

The first support 1310 of the first rotating object 1301 may be disposed on the first side of the driving object 1100. The first support 1310 may extend in a direction intersecting the direction in which the driving object 1100 extends. A length of the first support 1310 in the second direction DR2 may be smaller than a length of the carrier 600 in the second direction DR2 even when the first support 1310 is positioned to be parallel to the second direction DR2 (See FIG. 9). For example, the length of the first support 1310 may be smaller than a length of the first bar 601 included in the carrier 600.

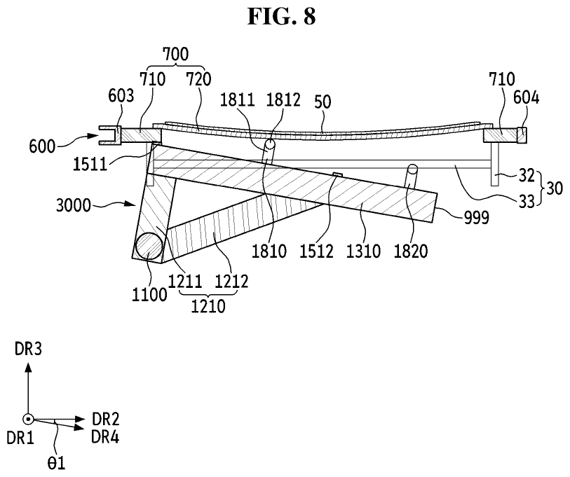

The first coupling portion 1210 of the first rotating object 1301 may connect the first support 1310 and the first side of the driving object 1100 to each other. For example, a side of the first coupling portion 1210 may be rotatably connected to the first side of the driving object 1100, and the other side of the first coupling portion 1210 may be connected to the first support 1310. For example, a portion of the other side of the first coupling portion 1210 may be connected to an end of the first support 1310, and another portion of the other side of the first coupling portion 1210 may be connected to a middle portion of the first support 1310. The first coupling portion 1210 may include a first coupling support 1211 (see FIG. 8) and a second coupling support 1212 (see FIG. 8). The first coupling support 1211 may be connected to the first side of the driving object 1100 and the end of the first support 1310, and the second coupling support 1212 may be connected to the first side of the driving object 1100 and the middle portion of the first support 1310.

The protrusions 1511 and 1512 of the first rotating object 1301 may include a first protrusion 1511 and a second protrusion 1512. The first protrusion 1511 and the second protrusion 1512 may be disposed on the first support 1310. For example, the first protrusion 1511 may be disposed on the first support 1310 to overlap a portion of the other side of the first coupling portion 1210, and the second protrusion 1512 may be disposed on the first support 1310 to overlap another portion of the other side of the first coupling portion 1210. When the carrier 600 is placed on the position changing device 3000, the first protrusion 1511 of the first rotating object 1301 may be placed to correspond to a first support member 610 close to the third bar 603 among the first support members 610 of the carrier 600, and the second protrusion 1512 of the first rotating object 1301 may be placed to overlap a first support member 610 in the middle among the first support members 610 of the carrier 600.

A second support 1320 of the second rotating object 1302 may be disposed on a second side of the driving object 1100. The second side of the driving object 1100 is opposite to the first side of the driving object 1100. The second support 1320 may extend in the direction intersecting the direction in which the driving object 1100 extends. A length of the second support 1320 in the second direction DR2 may be smaller than the length of the carrier 600 in the second direction DR2 even when the second support 1320 is positioned to be parallel to the second direction DR2 (See FIG. 9). For example, the length of the second support 1320 may be smaller than a length of the second bar 602 included in the carrier 600. The length of the second support 1320 may be equal to the length of the first support 1310. The second support 1320 may be parallel to the first support 1310. The second support 1320 may face the first support 1310.

A second coupling portion 1220 of the second rotating object 1302 may connect the second support 1320 and the second side of the driving object 1100 to each other. For example, a side of the second coupling portion 1220 may be rotatably connected to the second side of the driving object 1100, and the other side of the second coupling portion 1220 may be connected to the second support 1320. For example, a portion of the other side of the second coupling portion 1220 may be connected to an end of the second support 1320, and another portion of the other side of the second coupling portion 1220 may be connected to a middle portion of the second support 1320. The second coupling portion 1220 may include a first coupling support and a second coupling support. The first coupling support may be connected to the second side of the driving object 1100 and the end of the second support 1320, and the second coupling support may be connected to the second side of the driving object 1100 and the middle portion of the second support 1320.

A plurality of protrusions 1521 and 1522 of the second rotating object 1302 may include a third protrusion 1521 and a fourth protrusion 1522. The third protrusion 1521 and the fourth protrusion 1522 may be disposed on the second support 1320. For example, the third protrusion 1521 may be disposed on the second support 1320 to overlap a portion of the other side of the second coupling portion 1220, and the fourth protrusion 1522 may be disposed on the second support 1320 to overlap another portion of the other side of the second coupling portion 1220. When the carrier 600 is placed on the position changing device 3000, the third protrusion 1521 of the second rotating object 1302 may be placed to correspond to a second support member 620 close to the third bar 603 among the second support members 620 of the carrier 600, and the fourth protrusion 1522 of the second rotating object 1302 may be placed to overlap a second support member 620 in the middle among the second support members 620 of the carrier 600.

The first connecting portion 1410 may connect the first rotating object 1301 and the second rotating object 1302 to each other. The first connecting portion 1410 may be disposed between the first rotating object 1301 and the second rotating object 1302. For example, a side of the first connecting portion 1410 may be connected to the first support 1310 of the first rotating object 1301, and the other side of the first connecting portion 1410 may be connected to the second support 1320 of the second rotating object 1302. Specifically, a side of the first connecting portion 1410 may be connected to the middle portion of the first support 1310, and the other side of the first connecting portion 1410 may be connected to the middle portion of the second support 1320. The first connecting portion 1410 may extend along the transport direction (e.g., the first direction DR1) of the transport unit 31. For example, the first connecting portion 1410 may extend parallel to the driving object 1100.

The second connecting portion 1420 may connect the first rotating object 1301 and the second rotating object 1302 to each other. The second connecting portion 1420 may be disposed between the first rotating object 1301 and the second rotating object 1302. For example, a side of the second connecting portion 1420 may be connected to the first support 1310 of the first rotating object 1301, and the other side of the second connecting portion 1420 may be connected to the second support 1320 of the second rotating object 1302. Specifically, a side of the second connecting portion 1420 may be connected to an edge of the first support 1310, and the other side of the second connecting portion 1420 may be connected to an edge of the second support 1320. The second connecting portion 1420 may extend along the transport direction (e.g., the first direction DR1) of the transport unit 31. For example, the second connecting portion 1420 may extend parallel to the driving object 1100. The second connecting portion 1420 may face the first connecting portion 1410 in the second direction DR2.

The support members 1810 and 1820 may be disposed on the connecting portions 1410 and 1420. For example, a plurality of support members 1810 and 1820 may be disposed on the first connecting portion 1410 and the second connecting portion 1420. FIG. 6 illustrates an example in which four support members 1810 and 1820 are disposed on two connecting portions 1410 and 1420, two on each connecting portion. For example, two first support members 1810 protruding upward from the first connecting portion 1410 may be disposed on the first connecting portion 1410, and two second support members 1820 protruding upward from the second connecting portion 1420 may be disposed on the second connecting portion 1420.

Support members disposed on the same connecting portion may face each other. For example, the two first support members 1810 disposed on the first connecting portion 1410 may face each other in the first direction DR1. Support members disposed on different connecting portions may face each other. For example, a first support member 1810 on the first connecting portion 1410 and a second support member 1820 on the second connecting portion 1420 may face each other in the second direction DR2.

Each of the support members 1810 and 1820 may protrude upward from a corresponding connecting portion. For example, the first support members 1810 may be disposed on the first connecting portion 1410 to protrude in a direction intersecting the direction in which the first support 1310 (or the second support 1320) extends. Each of the support members 1810 and 1820 may protrude higher than the first support 1310 (or the second support 1320). In other words, an end of each of the support members 1810 and 1820 may be disposed higher than an upper surface of the first support 1310 (or the second support 1320). For example, when an imaginary extension line connecting the upper surface of the first support 1310 and the upper surface of the second support 1320 is defined as a first imaginary extension line IEL1, the first support members 1810 may protrude upward to intersect the first imaginary extension line IEL1. In addition, each of the support members 1810 and 1820 may protrude higher than the protrusions 1511, 1512, 1521 and 1522. In other words, the end of each of the support members 1810 and 1820 may be disposed higher than upper surfaces of the protrusions 1511, 1512, 1521 and 1522. For example, when an imaginary extension line connecting the upper surface of the first protrusion 1511 and the upper surface of the third protrusion 1521 is defined as a second imaginary extension line IEL2, the first support members 1810 may protrude upward to intersect the second imaginary extension line IEL2.

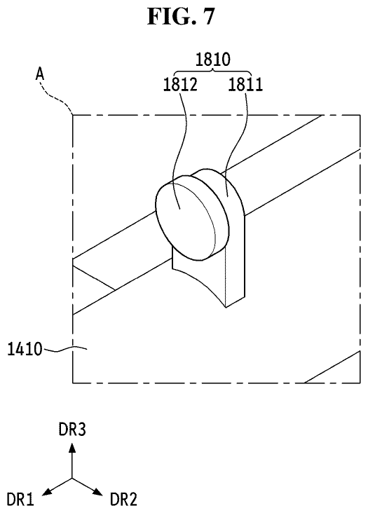

FIG. 7 is an enlarged view of part A of FIG. 6.

As illustrated in FIG. 7, a first support member 1810 may include an extension portion 1811 and a protrusion 1812. An end of the extension portion 1811 may be connected to the first connecting portion 1410. The extension portion 1811 may extend upward from the first connecting portion 1410. The protrusion 1812 may be disposed on an opposite end of the extension portion 1811. The protrusion 1812 may be rotatably connected to an opposite end of the extension portion 1811. For example, the protrusion 1812 may rotate about an axis parallel to the first direction DR1. The protrusion 1812 may have a cylindrical shape. However, the shape of the protrusion 1812 is not limited thereto and can be changed to various shapes.

When the carrier 600 is placed on the position changing device 3000, the first support members 1810 and the second support members 1820 may come into contact with the electrostatic chuck 720.

FIGS. 8, 9, 10 and 11 are views for explaining a method of changing the position of the carrier 600 using the position changing device 3000 according to an embodiment. For example, FIGS. 8 through 11 may be cross-sectional views taken along line I-I′ of FIG. 5.

First, as illustrated in FIGS. 5 and 8, the carrier 600 which has gone through the attaching process may be transferred to the position changing device 3000 along the transport unit 31. The substrate tray 700 may be accommodated in the carrier 600, and the substrate 50 may be placed on the electrostatic chuck 720 of the substrate tray 700. At this time, the carrier 600 loaded onto the position changing device 3000 may have a horizontal position. For example, the carrier 600 loaded onto the position changing device 3000 may be placed parallel to the connecting shaft 33 of the transport unit 31. Accordingly, the substrate tray 700 in the carrier 600 loaded onto the position changing device 3000, the electrostatic chuck 720 of the substrate tray 700, and the substrate 50 placed on the electrostatic chuck 720 may be placed parallel to the connecting shaft 33 of the transport unit 31.

As illustrated in FIG. 8, the electrostatic chuck 720 within the horizontal carrier 600 may sag downward along the direction of gravity (e.g., the third reverse direction). For example, the electrostatic chuck 720 may have a parabolic cross section which is convex in the direction of gravity. Accordingly, the substrate 50 on the electrostatic chuck 720 may also have a shape similar to that of the electrostatic chuck 720. For example, the substrate 50 may have a parabolic cross section which is convex in the direction of gravity.

As illustrated in FIG. 8, when the carrier 600 from the attaching device 2000 is loaded onto the position changing device 3000, the substrate tray 700 of the carrier 600 may be supported by the rollers 32. For example, the support plate 710 of the substrate tray 700 may be supported by the rollers 32. The position changing device 3000 may overlap the carrier 600 but may not contact the carrier 600. To this end, as in the example illustrated in FIG. 8, the supports 1310 and 1320 of the position changing device 3000 may be placed parallel to a fourth direction DR4. Accordingly, with an end 999 of the first support 1310 placed below the connecting shaft 33, the first support 1310 may form a predetermined angle θ1 with the connecting shaft 33. Here, the angle θ1 between the first support 1310 and the connecting shaft 33 may be an acute angle. Similarly, an angle between the second support 1320 and the connecting shaft 33 may be equal to the angle θ1 between the first support 1310 and the connecting shaft 33.

Next, as illustrated in FIG. 9, the position changing device 3000 may rotate counterclockwise toward the carrier 600. For example, the rotating objects 1301 and 1302 of the position changing device 3000 may be rotated until the supports 1310 and 1320 are placed parallel to the second direction DR2. Accordingly, the supports 1310 and 1320 may be placed parallel to the connecting shaft 33. Accordingly, the supports 1310 and 1320 may contact the carrier 600. In addition, the first support members 1810 and the second support members 1820 may contact the electrostatic chuck 720. For example, the protrusion 1812 of each of the support members 1810 and 1820 may contact the electrostatic chuck 720. At this time, since the first support members 1810 and the second support members 1820 protrude higher than the carrier 600, the electrostatic chuck 720 may have a parabolic cross section which is convex in a direction (e.g., the third direction DR3) opposite to the direction of gravity due to the first support members 1810 and the second support members 1820. Accordingly, the substrate 50 on the electrostatic chuck 720 may also have a parabolic cross section which is convex in the direction (e.g., the third direction DR3) opposite to the direction of gravity.

Next, an electrostatic force may be provided from the electrostatic chuck 720. For example, as illustrated in FIG. 9, when the supports 1310 and 1320 are placed parallel to the connecting shaft 33, a voltage may be applied to the electrostatic chuck 720 so that an electrostatic force can be provided from the electrostatic chuck 720. The substrate 50 may be attached to the electrostatic chuck 720 by this electrostatic force. For example, the electrostatic chuck 720 and the substrate 50 may be attached to each other while being convexly curved above the substrate tray 700 by the support members 1810 and 1820.

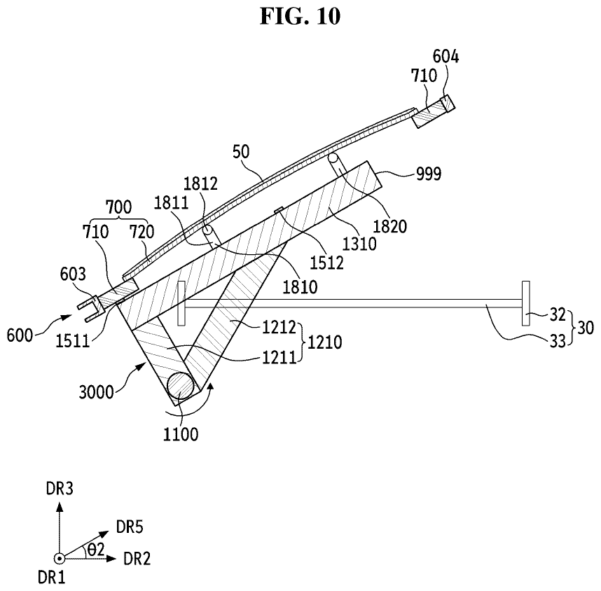

Next, as illustrated in FIG. 10, the position changing device 3000 may further rotate counterclockwise while in contact with the carrier 600. For example, the rotating objects 1301 and 1302 of the position changing device 3000 may be rotated until the supports 1310 and 1320 and the carrier 600 are placed parallel to a fifth direction DR5. Accordingly, with the end 999 of the first support 1310 placed above the connecting axis 33, the first support 1310 may form a predetermined angle θ2 with the connecting shaft 33. Here, the angle θ2 between the first support 1310 and the connecting shaft 33 may be an acute angle. At this time, the angle θ2 in FIG. 10 may be greater than the angle θ1 in FIG. 8 described above. Similarly, an angle between the second support 1320 and the connecting shaft 33 may be equal to the angle θ2 between the first support 1310 and the connecting shaft 33.

Next, as illustrated in FIG. 11, the position changing device 3000 may further rotate counterclockwise while in contact with the carrier 600. For example, the rotating objects 1301 and 1302 of the position changing device 3000 may be rotated until the supports 1310 and 1320 and the carrier 600 are placed parallel to a sixth direction DR6. Accordingly, with the end 999 of the first support 1310 placed above the connecting shaft 33, the first support 1310 may form a predetermined angle θ3 with the connecting shaft 33. Here, the angle θ3 between the first support 1310 and the connecting shaft 33 may be an obtuse angle. At this time, the angle θ3 in FIG. 11 may be greater than the angle θ2 in FIG. 10 described above. Similarly, an angle between the second support 1320 and the connecting shaft 33 may be equal to the angle θ3 between the first support 1310 and the connecting shaft 33. Therefore, as illustrated in FIG. 11, the carrier 600 may have a vertical position. For example, the carrier 600 may be placed almost vertically with respect to the connecting shaft 33 of the transport unit 31. Accordingly, the substrate tray 700 in the carrier 600 whose position has been changed by the position changing device 3000, the electrostatic chuck 720 of the substrate tray 700, and the substrate 50 placed on the electrostatic chuck 720 may also be placed almost vertically with respect to the connecting shaft 33 of the transport unit 31.

Next, after the carrier 600 is gripped by a vertical transport mechanism, the position changing device 3000 may rotate clockwise to return to its original position. For example, the rotating objects 1301 and 1302 of the position changing device 3000 may be rotated until the supports 1310 and 1320 are placed parallel to the fourth direction DR4 as illustrated in FIG. 8. Accordingly, the first and second support members 1810 and 1820 of the position changing device 3000 and the electrostatic chuck 720 in contact with each other may be separated. In other words, while the electrostatic chuck 720 is placed in a vertical position as illustrated in FIG. 11, a supporting force of the first support members 1810 and the second support members 1810 for the electrostatic chuck 720 may be removed. At this time, even if the supporting force of the first support members 1810 and the second support members 1810 is removed, the electrostatic chuck 720 and the substrate 50 in the vertical position can be maintained in a parabolic shape which is convex roughly in the second reverse direction as illustrated in FIG. 11.

The carrier 600 (e.g., the carrier 600 including a transport tray and the substrate 50) in the vertical position as illustrated in FIG. 11 may be loaded into the attaching device 2000 described above along the transport unit 31. For example, the carrier 600 in the vertical position may be transported along the transport unit 31 and loaded into the chamber 100 through the first gate G1 of the chamber 100 of FIG. 1. In the chamber 100, a deposition process may be performed on the substrate 50 accommodated in the vertical carrier 600. At this time, in the chamber 100, the substrate 50 may be provided with a deposition material while being maintained in the vertical position as illustrated in FIG. 11.

According to an embodiment, the electrostatic chuck 720 of the substrate tray 700 accommodated in the carrier 600 in a horizontal position may be supported by the support members 1810 and 1820. Therefore, while the carrier 600 is maintained in the horizontal position (e.g., before the position of the carrier 600 is changed), the electrostatic chuck 720 and the substrate 50 on the electrostatic chuck 720 may be maintained in a parabolic shape which is convex in a direction from the electrostatic chuck 720 toward the substrate 50. In other words, the electrostatic chuck 720 and the substrate 50 when the carrier 600 is in a horizontal position may have substantially the same shape as the electrostatic chuck 720 and the substrate 50 when the carrier 600 is in a vertical position. Therefore, a change in the shape of the electrostatic chuck 720 and the substrate 50 can be suppressed even during a position change of the carrier 600. If there is no support member, when the carrier 600 is changed from a horizontal position to a vertical position, the electrostatic chuck 720 may change from a state of sagging in the direction of gravity to a state of bulging in the direction from the electrostatic chuck 720 toward the substrate 50 as illustrated in FIG. 11. In other words, if there is no support member, the shape of the electrostatic chuck 720 and the substrate 50 may change rapidly when the position of the carrier 600 is changed. In this case, the adhesion between the electrostatic chuck 720 and the substrate 50 may be reduced. As a result, the substrate 50 may slip on the electrostatic chuck 720, causing an alignment error of the substrate 50. Otherwise, the substrate 50 may be separated from the electrostatic chuck 720. However, according to an embodiment, the above problem can be solved because before the position of the carrier 600 starts to be changed, the electrostatic chuck 720 and the substrate 50 are maintained in substantially the same shape as the electrostatic chuck 720 and the substrate 50 when the carrier 600 is in a vertical position. For example, according to an embodiment, even when the position of the carrier 600 is changed, the adhesion between the electrostatic chuck 720 and the substrate 50 can be stably maintained, and the alignment state of the substrate 50 can be maintained well. Therefore, deposition precision can be improved during a deposition process performed on the substrate 50 in the deposition device 1000.

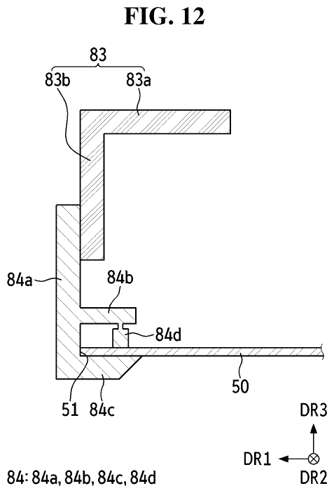

FIG. 12 is a cross-sectional view of the support 83 and a gripper 84 of the attaching device 2000 for a display device according to the embodiment.

As illustrated in FIG. 12, the support 83 may include a horizontal portion 83a and a vertical portion 83b. The vertical portion 83b may extend downward from a side of the horizontal portion 83a. For example, the vertical portion 83b may extend from a side of the horizontal portion 83a along the third reverse direction.

The gripper 84 may include a coupling portion 84a, a first extension portion 84c, a second extension portion 84b, and a pressing portion 84d.

The coupling portion 84a of the gripper 84 may be connected to the vertical portion 83b of the support 83.

The first extension portion 84c of the gripper 84 may extend along the first reverse direction from an edge of the coupling portion 84a.

The second extension portion 84b of the gripper 84 may be disposed on the first extension portion 84c. For example, the second extension portion 84b may be disposed between the first extension portion 84c and the support 83. The second extension portion 84b may extend along the first reverse direction from a middle portion of the coupling portion 84a.

The pressing portion 84d of the gripper 84 may be disposed between the first extension portion 84c and the second extension portion 84b. The pressing portion 84d may be movably connected to the second extension portion 84b. For example, the pressing portion 84d may move between the first extension portion 84c and the second extension portion 84b toward the first extension portion 84c or toward the second extension portion 84b. The pressing portion 84d may be, for example, connected to an actuator disposed in the second extension portion 84b.

The gripper 84 may grip the substrate 50 through the pressing portion 84d and the first extension portion 84c. For example, when the pressing portion 84d moves toward the first extension portion 84c, the substrate 50 may contact the first extension portion 84c and the pressing portion 84d. Here, the substrate 50 may be supported between the first extension portion 84c and the pressing portion 84d by the pressure applied by the pressing portion 84d.

The gripper 84 may also include only the coupling portion 84a and the first extension portion 84c described above. In other words, the second extension portion 84b and the pressing portion 84d can be omitted from the gripper 84 of FIG. 12.

According to a device and method for changing the position of a carrier for manufacturing a display device, deposition precision can be improved.

However, the effects of the present disclosure are not restricted to the one set forth herein. The above and other effects of the present disclosure will become more apparent to one of daily skill in the art to which the present disclosure pertains by referencing the claims.

The display device according to the embodiment can be applied to various electronic devices. The electronic device according to one embodiment includes the display device described above and may further include modules or devices having additional functions in addition to the display device.

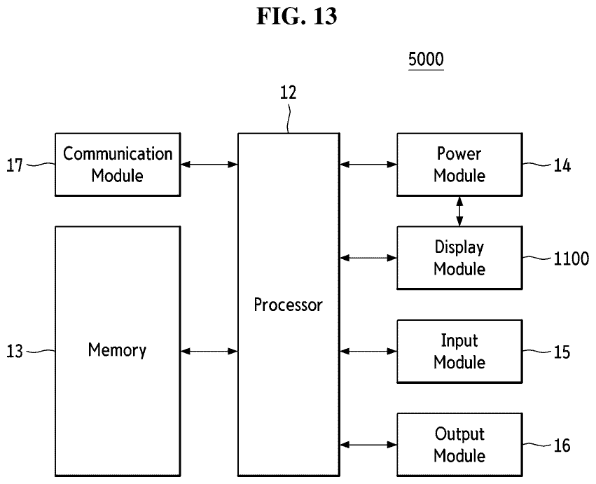

FIG. 13 is a block diagram of an electronic device according to one embodiment. Referring to FIG. 13, the electronic device 5000 according to one embodiment may include a display module (1100, e.g., a display device), a processor 12, a memory 13, and a power module 14. The electronic device 5000 may further include an input module 14, a non-image output module 15 and/or a communication module 16.

The electronic device 5000 may output various information in the form of images through the display module 1000. When the processor 12 executes an application stored in the memory 13, image information provided by the application may be provided to the user through the display module 1100. The power module 14 may include a power supply module such as a power adapter or a battery device, and a power conversion module that converts the power supplied by the power supply module to generate power required for the operation of the electronic device 5000. The input module 14 may provide input information to the processor 12 and/or the display module 1100. The non-image output module 15 may receive information other than images transmitted from the processor 12, such as sound, haptics, and light, and provide the information to the user. The communication module 16 is a module that is responsible for transmitting and receiving information between the electronic device 5000 and an external device, and may include a receiving unit and a transmitting unit.

At least one of the components of the electronic device 5000 described above may be included in the display device according to the embodiments described above. In addition, some of the individual modules functionally included in one module may be included in the display device, and others may be provided separately from the display device. For example, the display device includes a display module 1100, and the processor 12, memory 13, and power module 14 may be provided in the form of other devices within the electronic device 11 other than the display device.

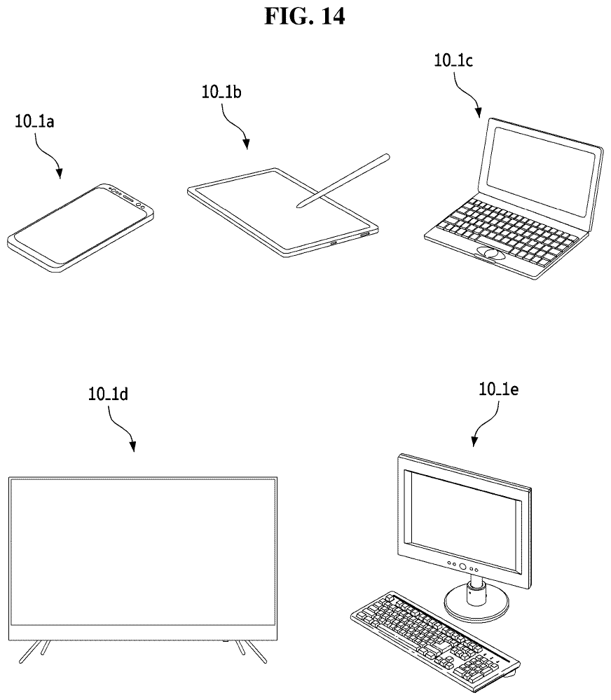

FIGS. 14, 15, and 16 are schematic diagrams of electronic devices according to various embodiments. FIGS. 14 to 16 illustrate examples of various electronic devices to which the display device according to the embodiments is applied.

FIG. 14 illustrates a smartphone 10_1a, a tablet PC 10_1b, a laptop 10_1c, a TV 10_1d, and a desk monitor 10_1e as examples of electronic devices.

In addition to the display module 1000, the smartphone 10_1a may include an input module such as a touch sensor and a communication module. The smartphone 10_1a may process information received through the communication module or other input modules and display the information through the display module of the display device.

In the case of tablet PCs 10_1b, laptops 10_1c, TVs 10_1d, and desk monitors 10_1e, they also include display modules and input modules similar to smartphones 10_1, and may additionally include communication modules in some cases.

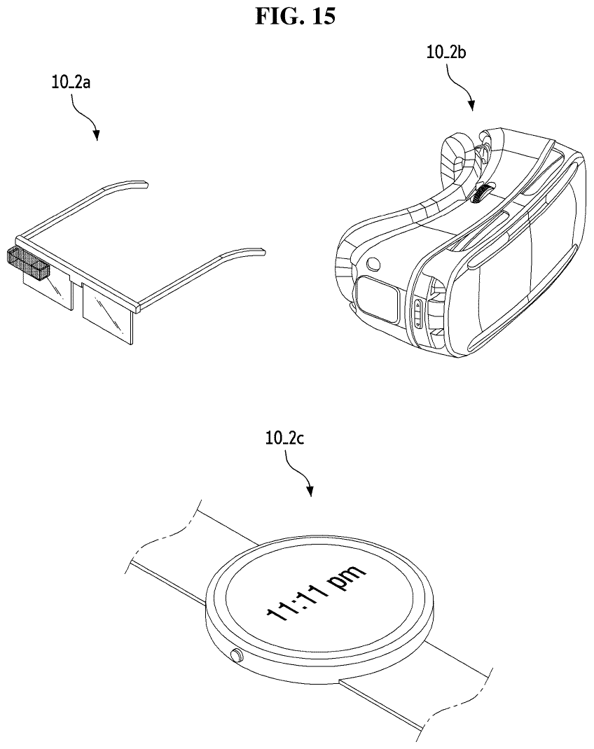

FIG. 15 shows an example of an electronic device including a display module being applied to a wearable electronic device. The wearable electronic device may be a smart glasses 10_2a, a head-mounted display 10_2b, a smart watch 10_2c, etc.

The smart glasses 10_2a and the head-mounted display 10_2b may include a display module that emits a display image and a reflector that reflects the emitted display screen and provides it to the user's eyes, thereby providing a virtual reality or augmented reality screen to the user.

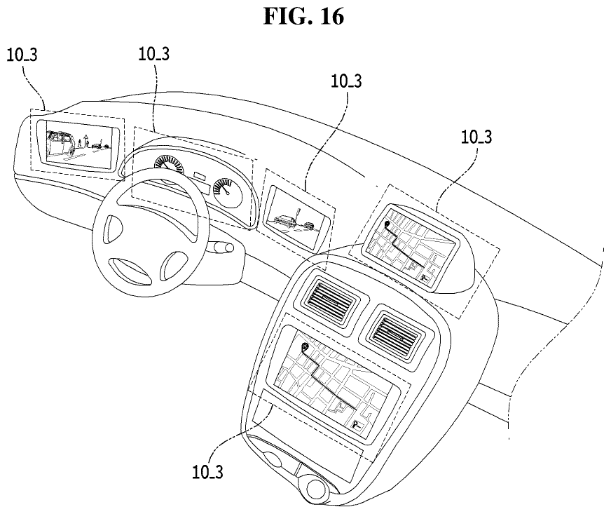

The smart watch 10_2c includes a biometric sensor as an input device, and may provide biometric information recognized by the biometric sensor to the user through the display module. FIG. 16 illustrates a case where an electronic device including a display module is applied to a vehicle. For example, the electronic device 10_3 may be applied to a dashboard, center fascia, etc. of a vehicle, or may be applied to a CID (Center Information Display) placed on a dashboard of a vehicle, or a room mirror display replacing a side mirror.

It will be able to be understood by one of ordinary skill in the art to which the present disclosure belongs that the present disclosure may be implemented in other specific forms without changing the technical spirit or essential features of the present disclosure. Therefore, it is to be understood that the exemplary embodiments described above are illustrative rather than being restrictive in all aspects. It is to be understood that the scope of the present disclosure are defined by the claims rather than the detailed description described above and all modifications and alterations derived from the claims and their equivalents fall within the scope of the present disclosure.

What is claimed is:

1. A device for changing a position of a carrier for manufacturing a display device, the device comprising:
a driving object disposed under a transport unit for transporting the carrier in which a substrate and a substrate tray are accommodated;
a first rotating object connected to a first side of the driving object;
a second rotating object connected to a second side of the driving object, opposite to the first side;
a connecting portion connecting the first rotating object and the second rotating object to each other; and
a support member on the connecting portion.

2. The device of claim 1, wherein the first rotating object is rotatably connected to the first side of the driving object, and the second rotating object is rotatably connected to the second side of the driving object.

3. The device of claim 1, wherein the first rotating object comprises:
a first support disposed at the first side of the driving object;
a first coupling portion connecting the first side of the driving object and the first support to each other; and
a first protrusion disposed on the first support.

4. The device of claim 3, wherein the second rotating object comprises:
a second support disposed at the second side of the driving object;
a second coupling portion connecting the second side of the driving object and the second support to each other; and
a second protrusion disposed on the second support.

5. The device of claim 4, wherein the connecting portion comprises a first connecting portion and a second connecting portion, which are disposed between the first support and the second support.

6. The device of claim 5, wherein the first connecting portion connects a middle portion of the first support and a middle portion of the second support to each other, and the second connecting portion connects an edge of the first support and an edge of the second support to each other.

7. The device of claim 6, wherein the support member comprises:
a first support member disposed on the first connecting portion; and
a second support member disposed on the second connecting portion.

8. The device of claim 7, wherein the first support member and the second support member face each other in a direction in which the first connecting portion and the second connecting portion are arranged.

9. The device of claim 7, wherein each of the first support member and the second support member is provided in a plural number.

10. The device of claim 9, wherein the plurality of first support members face each other, and the plurality of second support members face each other.

11. The device of claim 1, wherein the support member comprises:
an extension portion on the connecting portion; and
a protrusion rotatably connected to the extension portion.

12. The device of claim 1, wherein an axis of the driving object is parallel to a transport direction of the transport unit.

13. The device of claim 4, wherein an end of the support member is disposed closer to the substrate than an upper surface of each of the first support and the second support.

14. The device of claim 13, wherein the support member intersects a first imaginary extension line connecting the upper surface of the first support and the upper surface of the second support.

15. The device of claim 4, wherein an end of the support member is disposed closer to the substrate than an upper surface of each of the first protrusion and the second protrusion.

16. The device of claim 15, wherein the support member intersects a second imaginary extension line connecting the upper surface of the first protrusion and the upper surface of the second protrusion.

17. The device of claim 4, wherein a length of the first support is smaller than a length of the carrier when the first support is positioned parallel to the carrier, and a length of the second support is smaller than the length of the carrier when the second support is positioned parallel to the carrier.

18. The device of claim 17, wherein the length of the first support is smaller than a length of a first bar included in the carrier, and the length of the second support is smaller than a length of a second bar included in the carrier.

19. A method of changing a position of a carrier for manufacturing a display device, the method comprising:
preparing a position changing device which comprises a driving object, a first rotating object connected to a first side of the driving object and comprising a first support, a second rotating object connected to a second side of the driving object opposite to the first side and comprising a second support, a connecting portion connecting the first rotating object and the second rotating object to each other, and a support member on the connecting portion;
loading the carrier, in which a substrate tray and a substrate are accommodated, onto the position changing device in a horizontal direction through a transport unit;
bringing the support member and an electrostatic chuck of the substrate tray into contact with each other by rotating the position changing device in a first direction, which is a direction toward the carrier;
driving the electrostatic chuck so that the electrostatic chuck provides an electrostatic force; and
changing the position of the carrier from the horizontal position to a vertical position by further rotating the position changing device along the first direction.

20. An electronic device manufactured by a device for changing the position of a carrier for manufacturing a display device, the device comprising:
the display device,
wherein the device comprising:
a driving object disposed under a transport unit for transporting the carrier in which a substrate and a substrate tray are accommodated;
a first rotating object connected to a first side of the driving object;
a second rotating object connected to a second side of the driving object;
a connecting portion connecting the first rotating object and the second rotating object to each other; and
a support member on the connecting portion.
